(19) United States
(12) Patent Application Publication
(10) Pub. No.: US 2026/0320264 A1
(43) Pub. Date: Oct. 15, 2026

(54) METHOD TO IDENTIFY AND CHARACTERIZE SLUG FLOW

(71) Applicant: Schlumberger Technology Corporation, Sugar Land, TX (US)

(72) Inventors: Auzan Soedarmo, Lysaker (NO); Igor Koshelkov, Lysaker (NO)

(21) Appl. No.: 19/178,161

(22) Filed: Apr. 14, 2025

(51) Int. Cl. G06F 30/28

(52) U.S. Cl. CPC G06F 30/28

(57) ABSTRACT

A method for detecting and characterizing slug flow of a multiphase fluid in a pipeline includes receiving input data. The input data includes time-series data related to the multiphase fluid in the pipeline. The method also includes determining that a slug flow exists based upon the input data. The method also includes identifying a plurality of slug fronts and a plurality of slug tails in the slug flow. The method also includes determining characteristics of the slug flow based upon the slug fronts and the slug tails.

### BACKGROUND

Slug flow is a common occurrence in simultaneous flow of gas and liquid in a pipe. The flow is characterized by alternating passage of aerated liquid plugs and continuous gas pockets. Due to its inherent transient behavior, slug flow poses various operational challenges such as pipe fatigue and downstream separator flooding. Multiphase flow model(s) are available to compute important slug characteristics, such as slug length and frequency. The accuracy of such predictions is generally still low, primarily due to the uncertainties in the measurement itself. The measurement of slug length and frequency relies on largely subjective workflow post-processing of time-series data (e.g., holdup, fluid density, or pressure). Therefore, what is needed is a system and method that remove (or at least minimize) the subjective nature of this workflow, thereby improving the slug characteristics data quality and enabling a greater degree of automation for productization purposes.

### SUMMARY

A method for detecting and characterizing slug flow of a multiphase fluid in a pipeline is disclosed. The method includes receiving input data. The input data includes time-series data related to the multiphase fluid in the pipeline. The method also includes determining that a slug flow exists based upon the input data. The method also includes identifying a plurality of slug fronts and a plurality of slug tails in the slug flow. The method also includes determining characteristics of the slug flow based upon the slug fronts and the slug tails.

In another embodiment, the method includes receiving input data. The input data includes time-series data related to a multiphase fluid in a pipeline. The multiphase fluid includes oil, gas, water, or a combination thereof. The method also includes selecting a time window in the input data where operating conditions are steady-state. The method also includes filtering the input data to produce filtered data. The input data is filtered with a low-pass filter and/or a high-pass filter to remove noise. The input data is filtered within the time window. The method also includes determining that a slug flow exists based upon the filtered data. The slug flow is determined to exist in the multiphase fluid in the pipeline within the time window. The slug flow is determined to exist by determining that the filtered data shows a bimodal distribution. Determining that the filtered data shows a bimodal distribution includes determining a first bimodality criterion, a second bimodality criterion, and a third bimodality criterion. The filtered data is determined to show the bimodal distribution in response to at least two out of the first, second, and third bimodality criteria are satisfied. Determining the first bimodality criterion includes determining that a bimodality coefficient is greater than a first constant. The bimodality coefficient is determined based upon a skewness of the filtered data, an excess kurtosis in the filtered data, and a number of data points in the filtered data. The first constant is from 0.5 to 0.6. Determining the second bimodality criterion includes determining that an index is greater than a second constant. The index is determined based upon a mean of the filtered data, a number of data points in an i-th bin of the filtered data, a center of the i-th bin of the filtered data, and a number of the bins. The second constant is from 0.075 to 0.125. Determining the third bimodality criterion includes splitting the filtered data into first and second classes using an Otsu algorithm, and determining that an Ashman's D value is greater than a third constant. The Ashman's D value is determined based upon the mean of the first and second classes and a variance of the first and second classes. The third constant is from 1.5 to 2.5. The method also includes identifying a plurality of slug fronts, a plurality of slug tails, a plurality of slug front gradients, a plurality of slug tail gradients, a plurality of slug zones, and a plurality of bubble zones in the slug flow. Each of the slug fronts, the slug tails, the slug front gradients, the slug tail gradients, the slug zones, and the bubble zones is identified in response to determining that the filtered data shows the bimodal distribution. Each of the slug fronts, the slug tails, the slug front gradients, the slug tail gradients, the slug zones, and the bubble zones is identified by processing the filtered data forward in time from earliest to latest. Each of the slug fronts is identified in response to the filtered data increasing above an upper threshold which also marks a beginning of one of the slug zones and an end of one of the bubble zones. Each of the slug tails is identified in response to the filtered data decreasing below a lower threshold which also marks an end of one of the slug zones and a beginning of one of the bubble zones. Each of the slug front gradients is determined by dividing an absolute difference between the upper and lower thresholds with a time to reach the lower threshold using a first backward search starting from the corresponding slug front. An end point of the first backward search is assigned as a new slug front in response to the slug front gradient being less steep than the slug tail gradient that is its counterpart. Each of the slug tail gradients is determined by dividing the absolute difference between the upper and lower thresholds with a time to reach the upper threshold using a second backward search starting from the corresponding slug tail. An end point of the second backward search is assigned as a new slug tail in response to the slug front gradient being less steep than the slug tail gradient that is its counterpart. The method also includes determining characteristics of the slug flow. The characteristics are determined based upon the slug fronts and the slug tails. The characteristics include a slug frequency, a slug length, a slug hold-up, a bubble hold-up, or a combination thereof. The slug frequency is determined based upon a number of the slug fronts, a number of the slug tails, and a time period within which the filtered data is analyzed. The slug length is determined based upon a time when one of the slug fronts is identified, a time when one of the slug tails is identified, and a slug pattern velocity in response to the filtered data being based upon non-flowrate measurements of the multiphase fluid, or a liquid flowrate of the multiphase fluid, a void-in-slugs, and a cross-sectional area of the pipeline in response to the filtered data being based upon measurements of the liquid flowrate. The method also includes displaying the slug fronts, the slug tails, the slug front gradients, the slug tail gradients, the slug zones, the bubble zones, the characteristics of the slug flow, or a combination thereof. The method also includes performing an action in response to the characteristics of the slug flow.

It will be appreciated that this summary is intended merely to introduce some aspects of the present methods, systems, and media, which are more fully described and/or claimed below. Accordingly, this summary is not intended to be limiting.

### BRIEF DESCRIPTION OF THE DRAWINGS

The accompanying drawings, which are incorporated in and constitute a part of this specification, illustrate embodiments of the present teachings and together with the description, serve to explain the principles of the present teachings. In the figures:

FIG. 1 illustrates an example of a liquid volume fraction (e.g., holdup) time-series of slug flow, according to an embodiment.

FIGS. 2A-2C illustrate how a threshold selection may alter the determined slug characteristics such as slug frequency (i.e., the number of slugs within a defined time period) or slug length, according to an embodiment.

FIG. 3 illustrates a flowchart of a method for detecting and characterizing slug flow of a multiphase fluid in a pipeline, according to an embodiment.

FIG. 4 illustrates a graph showing a visualization of the two-threshold slug bubble identification, according to an embodiment.

FIG. 5 illustrates a graph showing a visualization of the breaking front and the trailing end detection, according to an embodiment.

FIG. 6 illustrates a graph showing a visualization of the uncertainty analysis of slug identification, according to an embodiment.

FIG. 7 illustrates an example of a computing system for performing at least a portion of the method(s) described herein, according to an embodiment.

### DETAILED DESCRIPTION

Reference will now be made in detail to embodiments, examples of which are illustrated in the accompanying drawings and figures. In the following detailed description, numerous specific details are set forth in order to provide a thorough understanding of the invention. However, it will be apparent to one of ordinary skill in the art that the invention may be practiced without these specific details. In other instances, well-known methods, procedures, components, circuits, and networks have not been described in detail so as not to unnecessarily obscure aspects of the embodiments.

It will also be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular embodiments and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

Attention is now directed to processing procedures, methods, techniques, and workflows that are in accordance with some embodiments. Some operations in the processing procedures, methods, techniques, and workflows disclosed herein may be combined and/or the order of some operations may be changed.

Objective Method to Identify and Characterize Slug Flow from Time-Series Data

The present disclosure provides a method that represents a robust and automated way of slug identification from multiphase flow measurements. More particularly, the method characterizes slug flow from time-series data in an objective and consistent manner. In other words, the method eliminates (or at least minimizes) the subjective, and therefore inconsistent, nature of slug flow characterization workflow from raw time-series data. Lack of consistency in this workflow in the past led to a large variability in the data quality of slug characteristics (e.g., length, frequency, void fraction), which consequently hindered slug flow model development.

The method may automatically: 1) detect the presence of slug flow from a time-series data using bimodality analysis, and 2) consistently determine the beginning (i.e., slug front) and end (i.e., slug tail) of each slug. The method may also determine slug characteristics data (e.g., slug length distribution and frequency). Compared to conventional methods, the method described herein does not rely on any arbitrarily defined threshold for detecting the slug fronts and tails. The method also differs from conventional methods in that it implements two different threshold values for slug front and tail, thereby reducing the chance of spurious slug detection. The method also differs from conventional methods in that the method does not rely on an arbitrary interpretation of certain statistical features (e.g., the intersection between empirical and idealized distribution) to determine the threshold values for slug front and tail. Some conventional methods depend upon the existence of slug flow to be manually pre-determined in advance. The method described herein does so automatically.

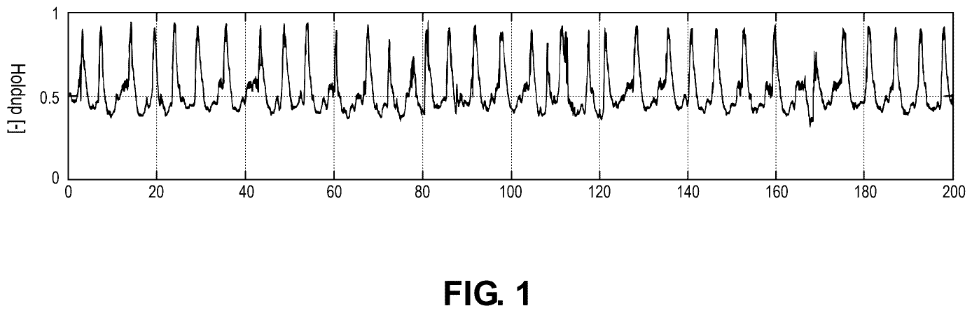

FIG. 1 illustrates an example of a liquid volume fraction (e.g., holdup) time-series of slug flow, according to an embodiment. The slug flow is marked by alternating high (indicating passages of aerated liquid plug or slug zone) and low holdup (indicating passages of gas pocket or bubble zone) periods. From this time-series, a user may deduce more detailed information about the slug characteristics, such as the frequency, length, void fraction, etc. More particularly, the raw time-series may be converted into a binary time-series, whereby 0 represents the bubble zones and 1 represents the slug zones. This conversion involves the selection of a threshold value above which the data is considered as part of slug zone and vice-versa. The threshold selection is largely a subjective process and may influence the computed slug characteristics, as illustrated in FIG. 1.

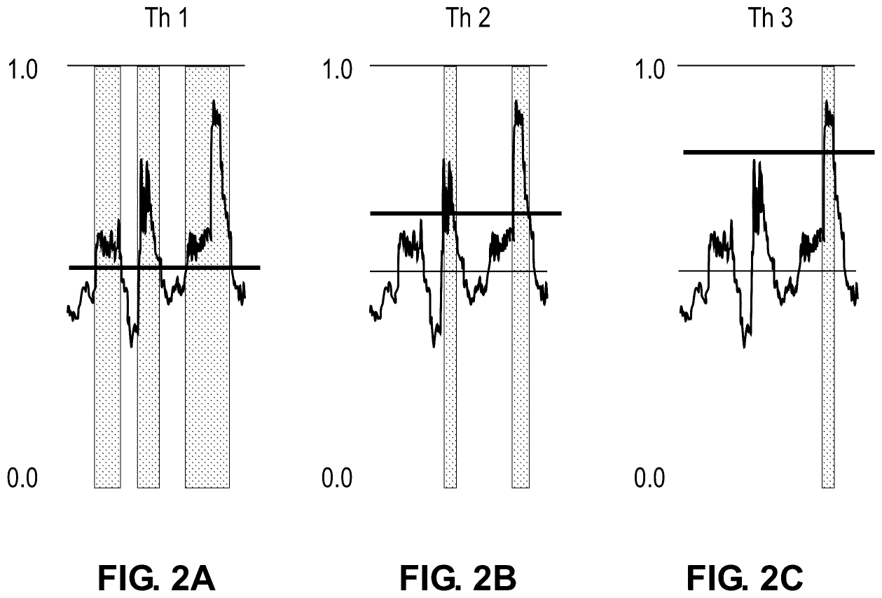

FIGS. 2A-2C illustrate how a threshold selection may alter the determined slug characteristics such as slug frequency (i.e., the number of slugs within a defined time period) or slug length, according to an embodiment. Another subjective element of this analysis is the determination of slug flow regime itself, as the conversion described above may not yield meaningful results if the raw time-series data does not contain slug flow features. The slug flow regime determination is also largely a subjective process. A quantitative way to distinguish slug flow may be to analyze the deflection on the translational/pattern velocity obtained via cross-correlation. However, this may not be possible unless there are two sensors placed adjacent to each other. Most investigators then rely on identifying a bimodal distribution from the probability density function of the time-series, which involves a subjective interpretation as well.

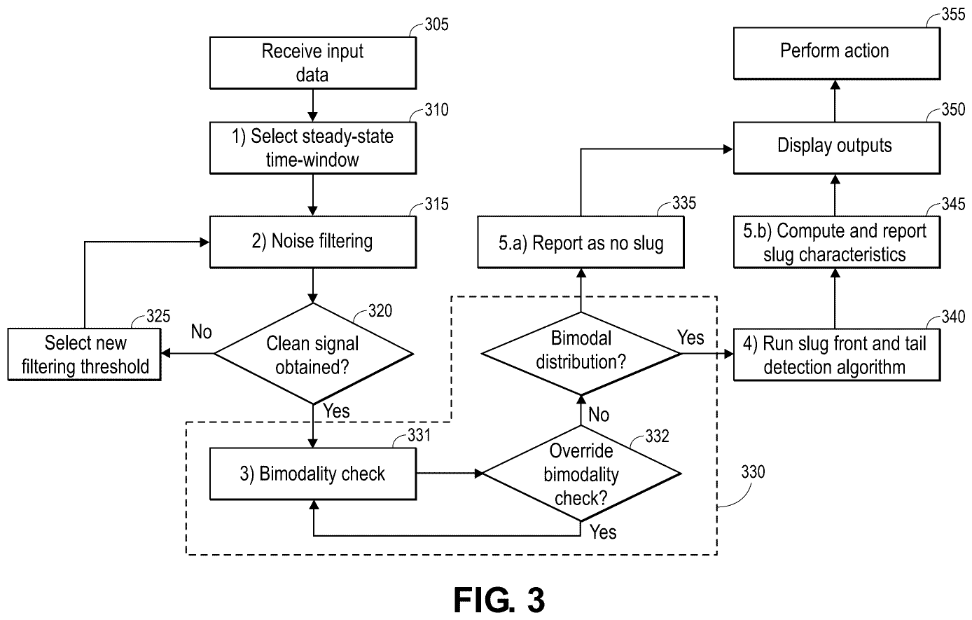

FIG. 3 illustrates a flowchart of a method 300 for detecting and characterizing slug flow of a multiphase fluid in a pipeline, according to an embodiment. An illustrative order of the method 300 is presented below; however, one or more portions of the method 300 may be performed in a different order, simultaneously, repeated, or omitted. At least a portion of the method 300 may be performed by a computing system.

### 3.1: Data Pre-Processing

The method 300 may include receiving input data, as at 305. The input data may be or include raw time-series data related to a multiphase fluid (e.g., oil and gas) in a pipeline.

The method 300 may also include selecting a time window in the input data where operating conditions are steady-state, as at 310. This may help to avoid the detection of operationally-induced slugging.

The method 300 may also include filtering the input data to produce filtered data, as at 315. More particularly, the input data in the time window may be filtered with a low-pass filter to remove noise. This may be omitted when processing synthetic time-series but is useful for field and/or experimental measurements. The method 300 provides the filtering process, but a user may determine the filtering threshold.

The method 300 may also include determining whether the noise has been removed from the input data, as at 320. In other words, has a clean signal been obtained? If not, the method 300 may loop back to 315 and select a new filter threshold (e.g., for the low-pass filter), as at 325.

### 3.2: Determination of Slug Flow Existence

Once the clean signal is obtained, the method 300 may include determining that a slug flow exists based upon the input data, as at 330. More particularly, this may include determining that the multiphase fluid in the pipeline includes a slug flow based upon the filtered data in the time window. The slug flow may be determined to exist in response to a probability density of the input data including or showing a bimodal distribution (i.e., bimodality), as at 331.

The bimodality may be quantified and/or determined using one or more (e.g., three) criteria. First, a bimodality coefficient (b) may be greater than a constant (C₁), as shown in Eq. 1. The variables g, k, and n represent the skewness, excess kurtosis, and number of data points in the time-series, respectively. By default, C₁ may be set to 5/9.

$$b = \frac{{g}^{2} + 1}{k + \frac{3 {( n - 1 )}^{2}}{( n - 2 ) ( n - 3 )}} > {C}_{1} \qquad ( 1 )$$

The bimodality coefficient criterion is convenient to calculate but has a weakness because its value may be high for unimodal distribution with high skewness and/or low kurtosis. Therefore, this criterion needs may be supplemented. The second criterion defines an index, B, as expressed in Eq. 2. Variables μ, mᵢ, xᵢ, and L denote the mean of the data, number of data points in the i-th bin, the center of the i-th bin, and the number of bins, respectively. The data may be split into a plurality of (e.g., 20) bins. The distribution may be determined to be bimodal if B>C₂, which is by default set to a predetermined value (e.g., 0.1).

$$B = \vert μ - {μ}_{M} \vert = \vert μ - \frac{{\sum }_{i = 1}^{L} {m}_{i} {x}_{i}}{{\sum }_{i = 1}^{L} {m}_{i}} \vert > {C}_{2} \qquad ( 2 )$$

The third criterion, called the Ashman's D, assumes bimodality first and then tests for unimodality. This means that the time-series data may be separated into two sub-classes {1, 2}. The criterion is expressed in Eq. 3, where μ and σ represent the mean and variance of the distribution. Ashman's D value of >C₃, which is by default set to a predetermined value (e.g., 2), indicates that two normally distributed data are sufficiently separated, and they may likely form a bimodal distribution when combined. The separation of the time-series into sub-classes 1 and 2 may be performed with an Otsu algorithm. This algorithm is explained further below, as it is also used as the principle for slug front and tail detections.

$$D = \frac{\vert {μ}_{1} - {μ}_{2} \vert}{\sqrt{2 ( {σ}_{1}^{2} + {σ}_{2}^{2} )}} > {C}_{3} \qquad ( 3 )$$

Slug flow may be deemed to exist if at least 2 of 3 bimodality criteria above are satisfied (e.g., bimodality score of >66.67%). The method 300 may allow a user to override the algorithm's recommendation, as at 332. For example, the C₁, C₂, and/or C₃ values may be modified (e.g., by a user), although the acceptable range may be limited inputs on these three constants.

On top of the three bimodality criteria above, the method 300 may include or activate a fourth (e.g., extended) bimodality criterion. This criterion is called the Hartigan's dip test. This test compares the empirical cumulative distribution function (CDF) of the time-series data with the best fitting unimodal CDF. The dip may be interpreted as the maximum distance between the empirical and best fit CDF. From the dip value, the method 300 may determine the likelihood (e.g., P-value) that the distribution is unimodal. The P-value calculation may be based on pre-tabulated simulation results for different sample sizes. Lower P-values may indicate stronger bimodality. A P-value of 0.05 or less may indicate strong bimodality while value between 0.05 and 0.1 indicates marginal bimodality. As it is generally more prudent to err on the side of detecting a false slug flow than false non-slug flow, the method 300 may consider a P-value of less than 0.1 to be bimodal by default. This value may also be adjusted by users. In an example, the “diptest 0.8.2” may be used. The Hartigan's dip test is offered as an optional criterion due to its' computational cost. Nonetheless, if this test is activated, it may modify the bimodality score computed based on the three basic criteria.

### 3.3: Slug Front and Tail Detection

In response to a determination that no slug flow exists (e.g., determining that the input data does not include a bimodal distribution, the method 300 may include reporting or displaying that no slug exists, as at 335. However, in response to a determination that the slug flow exists (e.g., determining that the input data includes a bimodal distribution), the method 300 may include detecting or identifying one or more slug fronts and one or more slug tails, as at 340. This may be detected/identified using a slug front and tail detection algorithm that is based on the multi-Otsu thresholding. Thresholding in image processing is a way to separate dark and bright areas of an image into a given number of intensity segments. Accordingly, one of the applications includes converting grayscale images into a binary format, black and white image. This is an analogy to what the method 300 is trying to achieve trying to separate the input data signal into slug and bubble zones.

The original Otsu's method searches for a single threshold that minimizes the intra-class variance according to the following Eq. 4:

$${σ}_{w}^{2} ( t ) = {ω}_{0} ( t ) {σ}_{0}^{2} ( t ) + {ω}_{1} ( t ) {σ}_{1}^{2} ( t ) \qquad ( 4 )$$

where ω₀ and ω₁ are the probabilities of the two classes separated by a threshold t, and σ₀² and σ₁² are variances of these two classes.

As demonstrated above, the selection of the threshold may impact the results. A single threshold derived from Otsu's algorithm may be susceptible to outliers and inhomogeneous data, particularly when the variance between classes differs by more than a predetermined threshold, which may be the case with field measurements. That being said, the single threshold method may be used to separate the time-series into two sub-classes for the Ashman's D bimodality test.

The method used herein for the slug front/tail detection is a variation of the original Otsu's method that computes thresholds for multiple classes. In this approach, it may be assumed that there are well-defined values in the signal corresponding to slugs and bubbles, as well as a grey zone in between that does not clearly belong to either the slug or bubble zone. In an example, multilevel thresholds may be determined. This may extend Eq. 4 to include a given number of classes, specifically in this case-three classes.

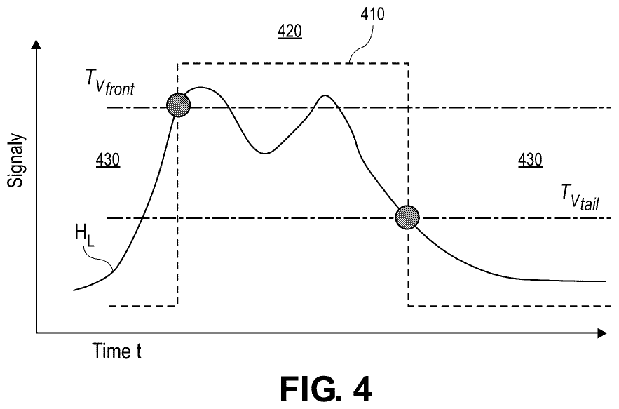

FIG. 4 illustrates a graph showing a visualization of the two-threshold slug bubble identification, according to an embodiment. One difference from single thresholding is that slug and bubble selection in this case depends on the previously observed values, not solely on global ones. Eq. 5 describes the selection algorithm for identifying slug or bubble zones at each time instance i. H_{L} represents the analyzed time signal (e.g., the filtered data). T_{Vfront} and T_{Vtail} are upper and lower thresholds identified from the signal Hz using the described multilevel Otsu's algorithm. One goal is to obtain a binary signal of 1 and 0 (e.g., the dashed line 410 in the shape of a square wave), which corresponds to slug and bubble zones, respectively. The transition to a slug zone 420 from a bubble zone 430 occurs when the signal H_{L} reaches the value of T_{Vfront}. Conversely, the transition to a bubble zone 430 from a slug zone 420 occurs when the signal value falls below the lower threshold, T_{Vtail}.

$${H}_{L} ( i ) > {T}_{{v}_{front}} \to slug \qquad ( 5 )$$

$${H}_{L} ( i ) < {T}_{{v}_{tail}} \to bubble$$

$$else \{ \begin{matrix}bubble ; if {H}_{L} ( i - 1 ) = bubble \\ slug , if {H}_{L} ( i - 1 ) = slug\end{matrix}$$

### 3.4: Breaking Front and Trailing End Detection

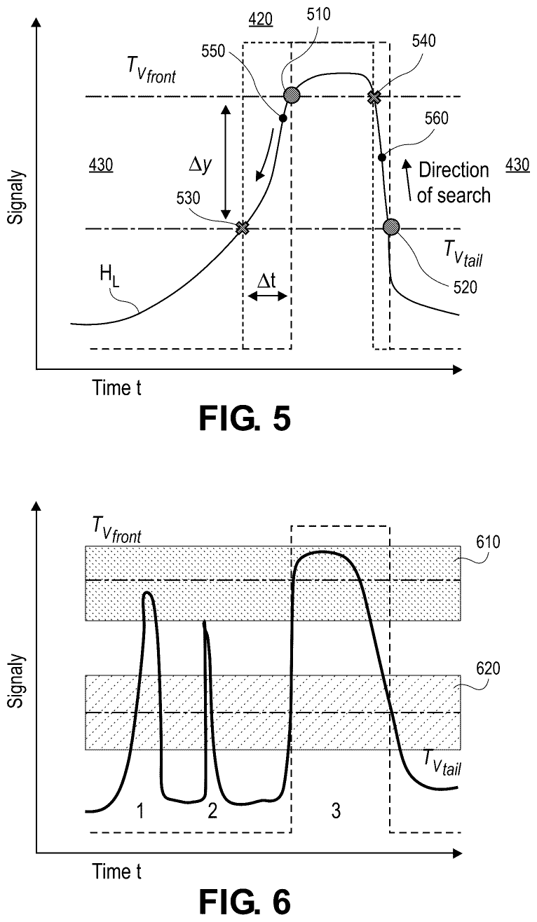

FIG. 5 illustrates a graph showing a visualization of the breaking front and the trailing end detection, according to an embodiment. In certain flow conditions, the shape of a slug might be different in its geometry to the one presented in FIG. 4. Here, the slug front 510 may be referred to as the transition from the bubble zone 430 to the slug zone 420. This is the part of the slug that arrives first in time. The transition to the bubble zone 430 afterward is referred to as the slug tail 520. There may be a gradient 550 between a secondary slug front 530 and the primary slug front 510, and a gradient 560 between the secondary slug tail 540 and the primary slug tail 520. This may lead to missing a substantial part of the slug body. To avoid this, the method 300 may optionally check the identified slug zone's gradients 550, 560 at the front and tail 510, 520. If the gradient 560 is steeper than the gradient 550, the gradient 560 is referred to as a breaking front, and the gradient 550 is referred as a trailing end. Conversely, if the gradient 550 is steeper is steeper than the gradient 560, the gradient 550 is referred to as the breaking front, and the gradient 560 is referred to as the trailing end.

The primary slug front and tail are identified as described in the previous section. Next, a backward search may be performed to obtain the secondary front at the first instance when the signal value falls below the T_{Vfront} threshold. Similarly, a secondary slug tail may be obtained through backward propagation at the first instance when the signal crosses the T_{Vtail} threshold. While the difference in signal amplitude between these thresholds is known, gradients at the slug front and tail may be calculated once time indices of the primary and secondary points are found.

The larger gradient may correspond to the breaking front, while the smaller gradient may correspond to the trailing end. The breaking front may be captured using the upper threshold. For the trailing end, a lower threshold may be used to include the longer feature. Eq. 5 may be valid in cases where the breaking front arrives first, followed by the trailing end. However, if the slug reverses, causing the trailing end to arrive first, a substantial part of the slug body may be missed. This extended processing approach ensures consistent and reliable results across different slug types, accommodating variations in slug behavior and geometry.

### 3.5: Uncertainty Analysis

The methodology for automated decision-making regarding the presence of slug flow and the testing of the signal to ascertain its suitability for processing is described above. Nonetheless, even if the signal passes these checks, there may still be performance limitations associated with the thresholding method outlined above for certain signals. To address these potential limitations, the method 300 may evaluate the uncertainty of the identified slugs and bubbles, as well as their associated characteristics. The next section provides detailed computations, while here, the foundational basis for the uncertainty evaluation is described. This evaluation may be conducted as part of 340 as depicted in FIG. 3. The two initially computed thresholds (e.g., described in 3.3 and 3.4 above), referred to as base values, may be individually adjusted upward and downward by a specified percentage, resulting in the identification of new slug fronts and tails.

FIG. 6 illustrates a graph showing a visualization of the uncertainty analysis of slug identification, according to an embodiment. A first (e.g., upper) region 610 and a second (e.g., lower) region 620 represent an arbitrarily selected range within which the thresholds are adjusted. It may be observed that within certain values of the upper threshold range, the feature indicated by number 1 is also included as a slug, thereby influencing the subsequent results. Even in the situation where positive identification of slug front and tail is not affected (e.g., feature 3), the shift in the thresholds may change the determined duration of a slug passage, which may influence the slug characteristics calculation as well.

The method 300 may also include determining one or more characteristics of the slugs, as at 345. The characteristics may be compared to the base characteristics. This comparison allows for the evaluation of the impact of threshold adjustments on the identified slug and bubble zones. By analyzing the differences between the base values and the adjusted thresholds, the method may quantify the uncertainty associated with the slug identification process and the obtained results.

### Calculation of Slug Characteristics

Step 340 (described above) may produce time instances of each slug front and tail pair. From this data, the method 300 may determine various slug characteristics such as slug frequency and/or slug length. The slug frequency may be determined with Eq. 6, where NF, NT, and Δt denote the number of slug fronts, number of slug tails, and the time period within which the time-series is analyzed, respectively.

$${f}_{S} = \frac{0.5 ( {N}_{F} + {N}_{T} )}{Δ t} \qquad ( 6 )$$

If the time-series are based on non-flowrate measurements (e.g., holdup, fluid density, and/or pressure), the length of the i-th slug (l_{S}ⁱ) may be determined with Eq. 7. The variables ty, t_{F}ⁱ, and Uₚ denote the time when the i-th slug front is identified, the time when the i-th slug tail is identified, and the slug pattern velocity, respectively. The Up may be obtained from cross-correlation if there are nearby and adjacent time-series measurements, by dividing the distance between the two adjacent sensors with the time-lag between the two time-series. If this is not feasible, the method 300 offers the option to use the pattern velocities from established closure relationships, such as a Bendiksen or Fabre model.

lₛⁱ=(tₜⁱ−t_{F}ⁱ)Uₚ (7)

If the time-series are based on flowrate measurements, then the calculation of slug length may be based on the integral of flowrates between the slug front and tail with respect to time (Eq. 8). Variables Q_{L}(t), α_{S}, and Aₚ denote the liquid flowrates, void-in-slugs, and pipe cross-sectional area, respectively. By default, the void-in-slugs quantity may be estimated with a correlation that uses the mixture velocity as input. However, if other relevant measurements such as pipe inclination, surface tension, and viscosity are available, other void-in-slugs correlations may be used as well.

$${l}_{S}^{i} = \frac{{\int }_{{t}_{F}^{i}}^{{t}_{T}^{i}} {Q}_{L} ( t ) d t}{( 1 - {α}_{S} ) {A}_{p}} \qquad ( 8 )$$

If the time-series are based on holdup (H_{L}) measurements, then the method 300 may also determine the holdup in both slug (H_{lS}ⁱ) and bubble zones (H_{lB}ⁱ) with Eqs. 9 and 10, respectively.

$${H}_{l S}^{i} = \frac{{\int }_{{t}_{F}^{i}}^{{t}_{T}^{i}} {H}_{L} ( t ) d t}{( {t}_{T}^{i} - {t}_{F}^{i} )} \qquad ( 9 )$$

$${H}_{l B}^{i} = \frac{{\int }_{{t}_{T}^{i}}^{{t}_{F}^{i + 1}} {H}_{L} ( t ) dt}{( {t}_{F}^{i + 1} - {t}_{T}^{i} )} \qquad ( 10 )$$

### Display and Action

The method 300 may also include displaying the slug fronts, the slug tails, the slug front gradients, the slug tail gradients, the slug zones, the bubble zones, the characteristics of the slug flow, or a combination thereof, as at 350.

The method 300 may also include performing an action in response to the characteristics of the slug flow, as at 355. The action may be or include generating and/or transmitting a signal (e.g., using a computing system) that recommends, instructs, or causes a physical action to occur to the multiphase fluid and/or the pipeline. The action may also or instead include performing the physical action. The physical action may include determining a size of a separator based on the slug length, estimating a corrosion rate based on the slug frequency, determining a risk of fatigue of the pipeline based on a difference between slug hold-up and the bubble hold-up, selecting a corrosion management strategy, or a combination thereof. In another embodiment, the physical action may be or include separating the gas and liquid portions from the multiphase fluid using the separator, introducing a corrosion inhibitor into the multiphase fluid and/or the pipeline to decrease the corrosion rate, repairing or replacing a segment of the pipeline in response to the corrosion or the fatigue, or a combination thereof.

### Summary

As described above, the method 300 may automatically determine the presence of slug flow in a time-series data and consequently identify slug fronts and tails in an objective manner. The presence of slug flow may be determined by combining several bimodality criteria. If 2 out of 3 bimodality criteria (or 3 out of 4 if the optional criteria) are activated, this may show the bimodal distribution. In response, the method 300 may recommend treating the time-series as slug flow. Users may override the recommendation on bimodality. If slug flow is deemed to be present, the method 300 may objectively identify the timestamps when each slug front and tail is detected. This may be based on an image processing technique to convert grayscale images into black/white images. The method 300 may also determine slug characteristics such as slug frequency, slug length(s), slug holdup(s), and/or bubble holdup(s). The objective nature of the method 300 lends itself well towards automation and applications in real-time systems.

### Exemplary Computing System

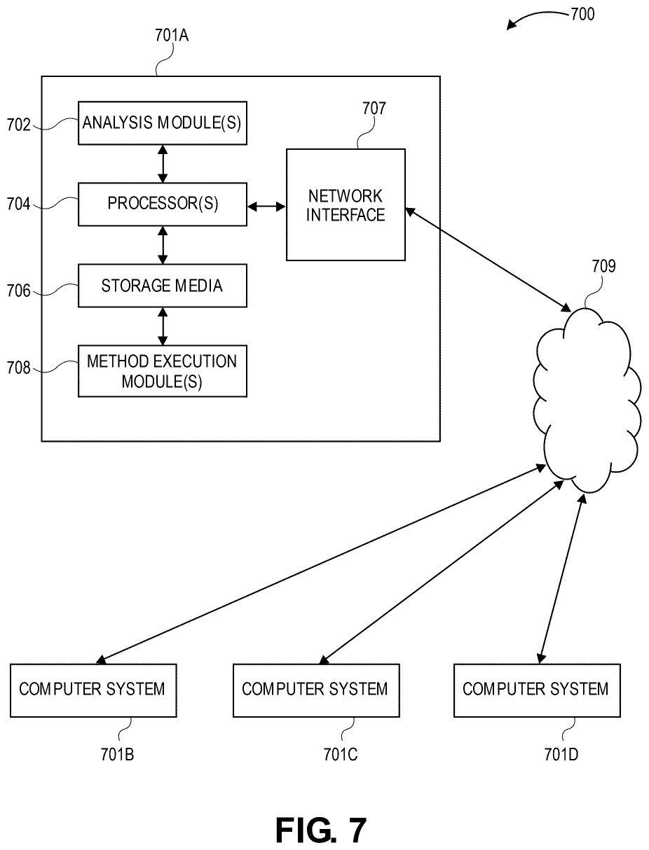

In some embodiments, the methods of the present disclosure may be executed by a computing system. FIG. 7 illustrates an example of such a computing system 700, in accordance with some embodiments. The computing system 700 may include a computer or computer system 701A, which may be an individual computer system 701A or an arrangement of distributed computer systems. The computer system 701A includes one or more analysis modules 702 that are configured to perform various tasks according to some embodiments, such as one or more methods disclosed herein. To perform these various tasks, the analysis module 702 executes independently, or in coordination with, one or more processors 704, which is (or are) connected to one or more storage media 706. The processor(s) 704 is (or are) also connected to a network interface 707 to allow the computer system 701A to communicate over a data network 709 with one or more additional computer systems and/or computing systems, such as 701B, 701C, and/or 701D (note that computer systems 701B, 701C and/or 701D may or may not share the same architecture as computer system 701A, and may be located in different physical locations, e.g., computer systems 701A and 701B may be located in a processing facility, while in communication with one or more computer systems such as 701C and/or 701D that are located in one or more data centers, and/or located in varying countries on different continents).

A processor may include a microprocessor, microcontroller, processor module or subsystem, programmable integrated circuit, programmable gate array, or another control or computing device.

The storage media 706 may be implemented as one or more computer-readable or machine-readable storage media. Note that while in the example embodiment of FIG. 7 storage media 706 is depicted as within computer system 701A, in some embodiments, storage media 706 may be distributed within and/or across multiple internal and/or external enclosures of computing system 701A and/or additional computing systems. Storage media 706 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLURAY® disks, or other types of optical storage, or other types of storage devices. Note that the instructions discussed above may be provided on one computer-readable or machine-readable storage medium, or may be provided on multiple computer-readable or machine-readable storage media distributed in a large system having possibly plural nodes. Such computer-readable or machine-readable storage medium or media is (are) considered to be part of an article (or article of manufacture). An article or article of manufacture may refer to any manufactured single component or multiple components. The storage medium or media may be located either in the machine running the machine-readable instructions, or located at a remote site from which machine-readable instructions may be downloaded over a network for execution.

In some embodiments, computing system 700 contains one or more method execution module(s) 708. In the example of computing system 700, computer system 701A includes the method execution module 708. In some embodiments, a single method execution module may be used to perform some aspects of one or more embodiments of the methods disclosed herein. In other embodiments, a plurality of method execution modules may be used to perform some aspects of methods herein.

It should be appreciated that computing system 700 is merely one example of a computing system, and that computing system 700 may have more or fewer components than shown, may combine additional components not depicted in the example embodiment of FIG. 7, and/or computing system 700 may have a different configuration or arrangement of the components depicted in FIG. 7. The various components shown in FIG. 7 may be implemented in hardware, software, or a combination of both hardware and software, including one or more signal processing and/or application specific integrated circuits.

Further, the steps in the processing methods described herein may be implemented by running one or more functional modules in information processing apparatus such as general purpose processors or application specific chips, such as ASICs, FPGAs, PLDs, or other appropriate devices. These modules, combinations of these modules, and/or their combination with general hardware are included within the scope of the present disclosure.

Computational interpretations, models, and/or other interpretation aids may be refined in an iterative fashion; this concept is applicable to the methods discussed herein. This may include use of feedback loops executed on an algorithmic basis, such as at a computing device (e.g., computing system 700, FIG. 7), and/or through manual control by a user who may make determinations regarding whether a given step, action, template, model, or set of curves has become sufficiently accurate for the evaluation of the subsurface three-dimensional geologic formation under consideration.

The foregoing description, for purposes of explanation, has been described with reference to specific embodiments. However, the illustrative discussions above are not intended to be exhaustive or limiting to the precise forms disclosed. Many modifications and variations are possible in view of the above teachings. Moreover, the order in which the elements of the methods described herein are illustrated and described may be re-arranged, and/or two or more elements may occur simultaneously. The embodiments were chosen and described in order to best explain the principles of the disclosure and its practical applications, to thereby enable others skilled in the art to best utilize the disclosed embodiments and various embodiments with various modifications as are suited to the particular use contemplated.

What is claimed is:

1. A method for detecting and characterizing slug flow of a multiphase fluid in a pipeline, the method comprising:
receiving input data, wherein the input data comprises time-series data related to the multiphase fluid in the pipeline,
determining that a slug flow exists based upon the input data;
identifying a plurality of slug fronts and a plurality of slug tails in the slug flow; and
determining characteristics of the slug flow based upon the slug fronts and the slug tails.

2. The method of claim 1, wherein the multiphase fluid comprises oil, gas, water, or a combination thereof.

3. The method of claim 1, further comprising:
selecting a time window in the input data where operating conditions are steady-state; and
filtering the input data to produce filtered data, wherein the input data is filtered with a low-pass filter and/or a high-pass filter in the time window to remove noise, and wherein the slug flow is determined to exist based upon the filtered data.

4. The method of claim 1, wherein the slug flow is determined to exist in response to determining that the input data shows a bimodal distribution.

5. The method of claim 4, wherein determining that the input data shows the bimodal distribution comprises determining that at least two of a first bimodality criterion, a second bimodality criterion, and a third bimodality criterion are satisfied.

6. The method of claim 5, wherein determining the first bimodality criterion comprises determining that a bimodality coefficient is greater than a constant, wherein the bimodality coefficient is determined based upon a skewness of the input data, an excess kurtosis in the input data, and a number of data points in the input data, and wherein the constant is from 0.5 to 0.6.

7. The method of claim 5, wherein determining the second bimodality criterion comprises determining that an index is greater than a constant, wherein the index is determined based upon a mean of the input data, a number of data points in an i-th bin of the input data, a center of the i-th bin of the input data, and a number of the bins, and wherein the constant is from 0.075 to 0.125.

8. The method of claim 5, wherein determining the third bimodality criterion comprises:
splitting the input data into first and second classes, wherein the input data is split using an Otsu algorithm; and
determining that an Ashman's D value is greater than a constant, wherein the Ashman's D value is determined based upon a mean of the first and second classes and a variance of the first and second classes, and wherein the constant is from 1.5 to 2.5.

9. The method of claim 1, further comprising displaying the slug fronts, the slug tails, the characteristics of the slug flow, or a combination thereof.

10. The method of claim 1, further comprising performing an action in response to the characteristics of the slug flow, wherein the action comprises generating and/or transmitting a signal that recommends, instructs, or causes a physical action to occur to the multiphase fluid and/or the pipeline.

11. A computing system, comprising:
one or more processors; and
a memory system comprising one or more non-transitory computer-readable media storing instructions that, when executed by at least one of the one or more processors, cause the computing system to perform operations, the operations comprising:
receiving input data, wherein the input data comprises time-series data related to a multiphase fluid in a pipeline,
determining that a slug flow exists based upon the input data;
identifying a plurality of slug fronts and a plurality of slug tails in the slug flow; and
determining characteristics of the slug flow based upon the slug fronts and the slug tails.

12. The computing system of claim 11, wherein the operations further comprise identifying a plurality of slug front gradients, a plurality of slug tail gradients, a plurality of slug zones, and a plurality of bubble zones in the slug flow by processing the input data forward in time from earliest to latest.

13. The computing system of claim 12, wherein each of the slug fronts is identified in response to the input data increasing above an upper threshold which also marks a beginning of one of the slug zones and an end of one of the bubble zones, and wherein each of the slug tails is identified in response to the input data decreasing below a lower threshold which also marks an end of one of the slug zones and a beginning of one of the bubble zones.

14. The computing system of claim 13, wherein each of the slug front gradients is determined by dividing an absolute difference between the upper and lower thresholds with a time to reach the lower threshold using a first backward search starting from the corresponding slug front, and wherein an end point of the first backward search is assigned as a new slug front in response to the slug front gradient being less steep than the slug tail gradient that is its counterpart.

15. The computing system of claim 14, wherein each of the slug tail gradients is determined by dividing the absolute difference between the upper and lower thresholds with a time to reach the upper threshold using a second backward search starting from the corresponding slug tail, and wherein an end point of the second backward search is assigned as a new slug tail in response to the slug front gradient being less steep than the slug tail gradient that is its counterpart.

16. A non-transitory computer-readable medium storing instructions that, when executed by one or more processors of a computing system, cause the computing system to perform operations, the operations comprising:
receiving input data, wherein the input data comprises time-series data related to a multiphase fluid in a pipeline,
determining that a slug flow exists based upon the input data;
identifying a plurality of slug fronts and a plurality of slug tails in the slug flow; and
determining characteristics of the slug flow based upon the slug fronts and the slug tails.

17. The non-transitory computer-readable medium of claim 16, wherein the characteristics comprise a slug frequency, a slug length, a slug hold-up, a bubble hold-up, or a combination thereof.

18. The non-transitory computer-readable medium of claim 17, wherein the slug frequency is determined based upon a number of the slug fronts, a number of the slug tails, and a time period within which the input data is analyzed.

19. The non-transitory computer-readable medium of claim 17, wherein the slug length is determined based upon a time when one of the slug fronts is identified, a time when one of the slug tails is identified, and a slug pattern velocity in response to the input data being based upon non-flowrate measurements of the multiphase fluid.

20. The non-transitory computer-readable medium of claim 17, wherein the slug length is determined based upon a liquid flowrate of the multiphase fluid, a void-in-slugs, and a cross-sectional area of the pipeline in response to the input data being based upon measurements of the liquid flowrate.
